(19) United States
(12) Patent Application Publication
(10) Pub. No.: US 2012/0329228 A1
(43) Pub. Date: Dec. 27, 2012

(54) METHOD FOR FORMING A STRAINED SEMICONDUCTOR CHANNEL

(76) Inventors: Haizhou Yin, New York, NY (US); Zhijiong Luo, New York, NY (US); Huilong Zhu, New York, NY (US)

(21) Appl. No.: 13/380,019

(22) PCT Filed: Aug. 9, 2011
(86) PCT No.: PCT/CN11/01311

§ 371 Date: Dec. 21, 2011

(30) Foreign Application Priority Data
Jun. 23, 2011 (CN) 201110171241.9

(51) Int. Cl. H01L 21/336

(52) U.S. Cl. 438/285; 257/E21.409

(57) ABSTRACT

The invention relates to a method of forming a strained semiconductor channel. According to the invention, a strained channel is formed after the annealing of source/drain, by which it does not only avoid the strained semiconductor channel from being exposed to the high-temperature source/drain annealing process, but also avoid a loss of the semiconductor layer since it reduces the number of processing steps that the strained semiconductor channel has to experience. Besides, because the etching rate of the ion implantation region is significantly greater than the etching rate of the surrounding portion of the relaxed layer into which no ions are implanted, the etching depth can be easily controlled.

### FIELD OF THE INVENTION

The invention relates to the semiconductor field, and in particular relates to a method for forming a strained semiconductor channel.

### BACKGROUND OF THE INVENTION

As the feature size of devices continuously reduces, the strained channel engineering with the purpose of improving the channel carrier mobility performs an increasingly important role. Theoretical and empirical researches have proved that when a stress is applied into the channel of a transistor, the carrier mobility of the transistor will be enhanced or reduced; however, it is also known that electron and hole have different responses to the same type of strain. For example, applying compressive stress in the direction of current flow is advantageous for improving hole mobility, but is disadvantageous for electron mobility. While applying tensile stress is advantageous for improving electron mobility, but is disadvantageous for hole mobility. In particular, as for an NMOS device, introducing tensile stress along the channel direction improves electron mobility in the channel; in another respect, as for a PMOS device, introducing compressive stress along the channel direction improves hole mobility in the channel. According to this theory, many methods have been developed, wherein one method is to generate “global strain”, that is, generating from the substrate the strain applied to the overall transistor device area, the global strain is generated by use of structures such as strained Si/SiGe relaxed layer, and strained Si on insulator. However, in the conventional method for forming a strained Si channel, prior to the process of device manufacturing (e.g., shallow trench isolation (STI), gate formation and etc.), a strained Si cladding layer must be formed firstly on, e.g., a SiGe layer. This causes problems as follows: (1) during the process of device manufacturing, the strained Si cladding layer may suffer loss by, for example, the pad oxidation process in STI process, the sacrificial oxidation process prior to the gate formation process, multiple wet chemical cleaning process and so on; (2) the strained Si cladding layer may relax (the stress is released) in the steps at a high-temperature, for example, the annealing process for activating the source/drain dopant may cause the stress in the Si cladding layer to be released.

One solution is to etch a portion of the relaxed SiGe layer after removing the replacement gate, and to epitaxially grow a strained semiconductor layer at the location where the relaxed SiGe layer is removed so as to form a channel, whereby avoiding the strained semiconductor channel being exposed to high-temperature source/drain annealing, and avoiding a loss of the semiconductor layer since the processing steps to be experienced by the strained semiconductor channel are reduced. However, such solution involves etching of the single material of SiGe, so the problem where the etching depth is hard to control exists due to selectivity ratio. Although SiGe may be utilized to form an etch stop layer, this undoubtedly will increase the difficulty in epitaxial growth process, and the effect of controlling the etching is not significant.

### SUMMARY OF THE INVENTION

Based on the problem stated above, the present invention provides a new method for forming a strained semiconductor channel, comprising:

forming a relaxed SiGe layer on a semiconductor substrate;

forming a first gate structure and a spacer surrounding the first gate structure on the relaxed layer;

forming a source and a drain in the relaxed layer on opposite sides of the first gate structure;

forming an inter-layer dielectric layer on the relaxed layer, the first gate structure and the spacer;

planarizing the inter-layer dielectric layer to expose the first gate structure;

removing the first gate structure to form an opening, whereby exposing the relaxed layer;

performing ion implantation into the opening to form an ion implantation region in the relaxed layer;

etching the ion implantation region to form a trench in the relaxed layer;

epitaxially growing a semiconductor epitaxial layer in the trench to form a strained semiconductor channel; and

forming a second gate structure on the semiconductor epitaxial layer.

According to the invention, a strained channel is formed after performing annealing of the source/drain, by which it does not only avoid the strained semiconductor channel from being exposed to the high-temperature source/drain annealing process, but also avoid a loss of the semiconductor layer since it reduces the number of the processing steps to be experienced by the strained semiconductor channel. Besides, because the etching rate of the ion implantation region is significantly greater than the etching rate of the surrounding portions of the relaxed layer into which no ions are implanted, the etching depth can be easily controlled.

### BRIEF DESCRIPTION OF THE DRAWINGS

A best understanding of the embodiments may be obtained by reference to descriptions below and the drawings for illustrating the embodiments. In the drawings:

FIG. 1 is a profile of a structure where a relaxed layer is formed on a substrate;

FIG. 2 is a profile of a structure where a first gate structure and a spacer are formed on the relaxed layer;

FIG. 3 is a profile of a structure where an inter-layer dielectric layer is formed;

FIG. 4 is a profile of a structure where a chemical mechanical planarization (CMP) process is implemented;

FIG. 5 is a profile of a structure where the exposed first gate structure is removed;

FIG. 6 is a profile of a structure where ion implantation is performed;

FIG. 7 is a profile of a structure where the ion implantation region is removed to form a trench;

FIG. 8 is a profile of a structure where a semiconductor epitaxial layer is formed; and

FIG. 9 is a profile of a structure where a second gate structure is formed.

### DETAILED DESCRIPTION OF THE PREFERRED EMBODIMENTS

One or more aspects of the embodiment of the present invention are described below with reference to the drawings, wherein generally the same element is denoted by the same reference sign throughout the drawings. In the following description, in order for illustration, many specifics are discussed in order to provide thorough understanding of one or more aspects of the embodiment of the present invention. However, it is obvious for those skilled in the art that one or more aspects of the embodiment of the invention can be implemented by making use of few of the specifics.

In addition, although particular features or aspects of the embodiment are disclosed by only one of the implementing modes, yet such features or aspects may be incorporated with other features or aspects of other implementing modes which may be desired and advantageous for any given or particular application.

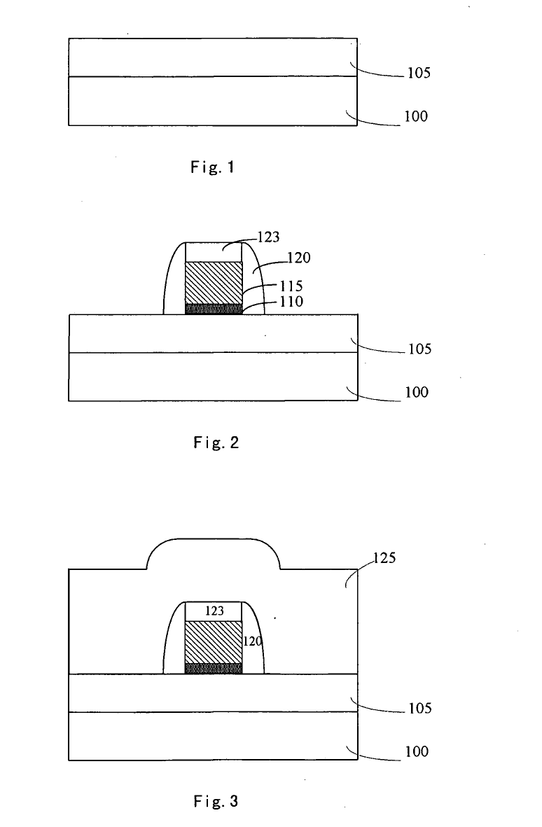

First, a relaxed layer 105 is formed on a substrate 100 (e.g., Si, and Silicon on insulator (SOI)), as shown in FIG. 1. The relaxed layer may be formed of SiGe. In an embodiment of the relaxed SiGe layer, the percentage of Ge atom in the relaxed SiGe layer 105 gradually varies, for example, from about 20% to 100% along the direction away from the substrate 100, that is, x in the Si₁₋ₓGeₓ gradually varies from about 0.2 to 1. Here, the specific numerical value of the composition of the relaxed SiGe layer 105 is only for the purpose of showing an example, those of ordinary skill in the art may select other appropriate compositions (i.e. re-select the variation range for x) in accordance with practical demand, and the gradual variation of x may be in various forms such as linear variation, hyperbolic variation, and exponential variation.

Thereafter, a first gate structure (as a sacrificial gate stack, which may comprise a first dielectric layer 110, a first gate layer 115 located on the first dielectric layer 110 and a cap layer 123) and a spacer 120 surrounding the first dielectric layer 110 and the first gate layer 115 are formed on the relaxed layer 105, as shown in FIG. 2. The first dielectric layer 110 generally is formed of oxide or nitride, e.g., SiO₂. The first gate layer 115, is formed of, e.g., polysilicon. The cap layer 123, is formed of, e.g., nitride. The spacer 120 generally consist of one of oxide, nitride, nitrogen oxide, carbide, and carbon oxide or other low-K materials, e.g., silicon nitride. Other materials known in the art also may be selected for the structure. As an example of the invention, the first dielectric layer 110 may have a thickness of about 1-5 nm, the first gate layer 115 may have a thickness of about 20-70 nm, and the spacer 120 may have a thickness of about 10-40 nm. Process steps above mentioned are a part of the conventional technology, which would not be further discussed here.

After forming the first gate structure, conventional methods such as ion implantation and high-temperature annealing may be employed to form a source/drain in the relaxed layer on opposite sides of the first gate structure (not shown in the drawings).

Then, an inter-layer dielectric layer 125 is formed on the relaxed layer, the first gate structure and the spacer, as shown in FIG. 3. The inter-layer dielectric layer 125 may consist of a material like undoped silica, various doped silica (such as borosilicate glass and borophosphosilicate glass), and silicon nitride. The method for forming the inter-layer dielectric layer 125 is for example deposition processes, including but not limited to chemical vapor deposition (CVD), plasma assisted CVD, atomic layer deposition (ALD), evaporation, reactive sputtering, chemical solution deposition or other similar deposition processes.

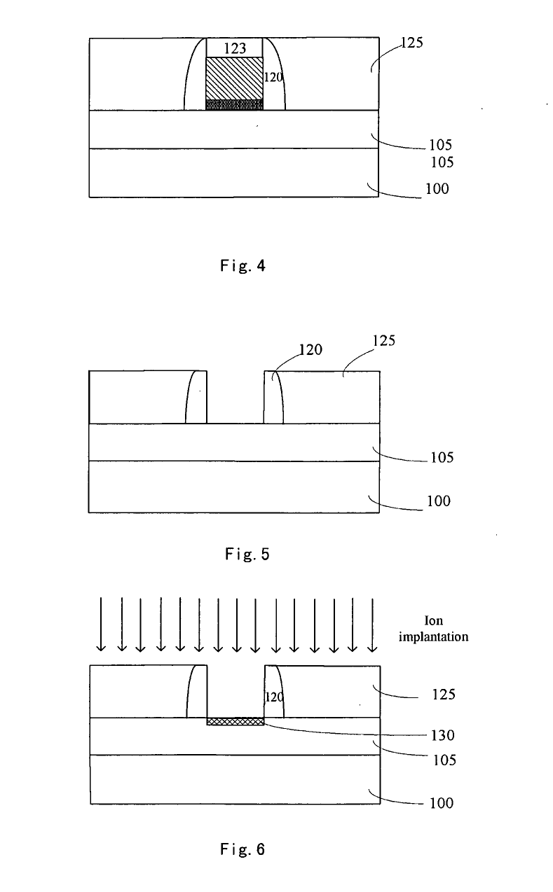

Next, chemical mechanical planarization (CMP) process is performed to the inter-layer dielectric layer to expose the first gate structure, as shown in FIG. 4.

Then, the first gate structure is removed to form an opening, whereby the relaxed layer 105 is exposed, as shown in FIG. 5. Wherein, in the case where the cap layer 123 exists in the first gate structure, additional CMP process or reactive ion etching (RIE) process should be firstly performed to remove the cap layer. Next, the first gate layer 115 and the first dielectric layer 110 are sequentially removed. The step may be implemented by use of any method known in the art, for example, wet etching or dry etching.

Next, ion implantation is performed into the opening to form an ion implantation region 130 in the relaxed layer, as shown in FIG. 6. As an example of the present invention, the dopants used in the ion implantation may be P, As or the combination of P and As, the dosage may be in a range of about 5×10¹³−4×10¹⁵ cm⁻³, and the implantation energy may be 1 k-3 keV. In the embodiment of the invention, the depth of the ion implantation region can be controlled easily by controlling the energy of the ion implantation, for example, controlling the depth of the ion implantation region 130 to be about 3 nm-10 nm.

Selectively, annealing is performed thereafter, for example, within a temperature range of about 700-800° C.

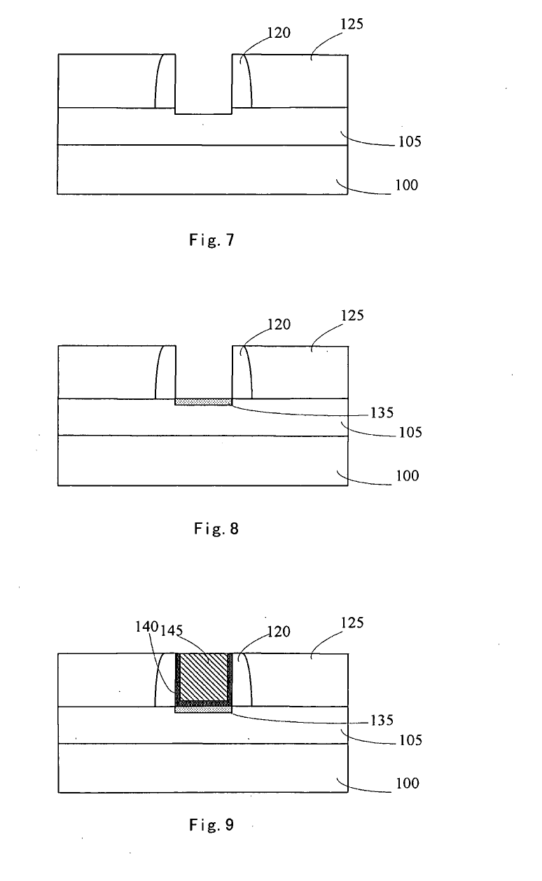

Next, the ion implantation region 130 is etched to form a trench in the relaxed layer, as shown in FIG. 7. The etching may be implemented by use of known techniques in the art, for example, wet etching or dry etching. As for the relaxed SiGe layer, for example, dry etching that makes use of NF₃ and Cl₂ may be used. Because the etching rate of the ion implantation region 130 is significantly greater than the etching rate of the surrounding portion of the relaxed layer into which no ions are implanted, the etching depth can be easily controlled. The best electron mobility may be achieved by an appropriate thickness of the channel.

Then, semiconductor epitaxial growth is performed in the trench to form a semiconductor epitaxial layer 135, as shown in FIG. 8. Wherein, the epitaxial layer material has a lattice constant different from that of the relaxed layer so as to form a strained semiconductor channel. The epitaxial growth may be performed by, for example, metal organic chemical vapor deposition (MOCVD) or molecular beam epitaxy (MBE). As an example of the invention, the semiconductor epitaxial layer may consist of at least one of a Si epitaxial layer, a Ge epitaxial layer and a SiGe epitaxial layer (wherein the percentage of Ge atom may be adjusted freely), which, in combination with the relaxed SiGe layer, introduces strain into the formed epitaxial layer, i.e. the channel, such that the electron or hole mobility in the channel is enhanced, which is advantageous for improving the performance of the MOS device. The semiconductor epitaxial layer may have a thickness of about 5-10 nm. The top surface of the epitaxial layer 135 may be on the same plane as the top surface of the relaxed layer 105 (as shown in FIG. 8), and also may be not on the same plane (not shown), however, it should be within the tolerance permitted for the semiconductor process.

If the epitaxial layer is formed of Si, usually a tensile stress channel may be formed, which is thus advantageous for adjusting the electron mobility of an n-type device; if the epitaxial layer is formed of Ge, a compressive stress channel may be formed, which is thus advantageous for adjusting the hole mobility of an p-type device; if the epitaxial layer is formed of SiGe, the proportion of Ge may be adjusted to thereby control the generation of compressive stress or tensile stress on both sides of the formed channel. Therefore, the embodiment of the invention is applicable to a pMOSFET or an nMOSFET.

Then, a second gate dielectric layer 140 and a second gate layer 145 are formed on the surface of the aforesaid structure and planarized to the inter-layer dielectric layer so as to form a second gate structure, as shown in FIG. 9. The second gate dielectric layer 140 and the second gate layer 145 may be formed by, for example, deposition processes, including but not limited to chemical vapor deposition (CVD), plasma assisted CVD, atomic layer deposition (ALD), evaporation, reactive sputtering, chemical solution deposition or other similar deposition processes. The second gate dielectric layer may consist of one of SiO₂ and high-K dielectric material selected from ZrO₂, HfO₂, Al₂O₃, HfSiO, HfSiON and/or the combinations thereof. The second gate layer comprises a work function metal gate (TiN) and a metal conductor layer (TiAl), which may have polysilicon thereon. As an example of the invention, the second gate dielectric layer 140 may have a thickness of about 1-5 nm.

Thereafter, the process of semiconductor manufacturing may be performed in accordance with a conventional method, for example, forming contact holes and metalized interconnection so as to form a MOS device.

In the embodiment, a strained channel 135 is formed after the source/drain annealing, by which it not only avoids the strained semiconductor channel being exposed to high-temperature source/drain annealing process in the conventional MOS process, but also avoids a loss of the semiconductor layer since it reduces the processing steps to be experienced by the strained semiconductor channel. Besides, because the etching rate of the ion implantation region formed in the relaxed layer is significantly greater than the etching rate of the surrounding portion of the relaxed layer into which no ions are implanted, the etching depth can be easily controlled, so as to control the thickness of the channel region ultimately formed, thus the stress generated on both sides of the channel region may be further controlled.

The above is only a preferred embodiment of the present invention, which does not intend to make any limitation to the invention. Therefore, various modifications and variations may be made to the invention without departing from the principle of the technical method of the present invention and the scope defined by the attached claims.

What is claimed is:

1. A method for forming a strained semiconductor channel, comprising:
forming a relaxed SiGe layer on a semiconductor substrate;
forming a first gate structure and a spacer surrounding the first gate structure on the relaxed layer;
forming a source and a drain in the relaxed layer on opposite sides of the first gate structure;
forming an inter-layer dielectric layer on the relaxed layer, the first gate structure, and the spacer;
planarizing the inter-layer dielectric layer to expose the first gate structure;
removing the first gate structure to form an opening, whereby exposing the relaxed layer;
performing ion implantation into the opening to form an ion implantation region in the relaxed layer;
etching the ion implantation region to form a trench in the relaxed layer;
epitaxially growing a semiconductor epitaxial layer in the trench to form a strained semiconductor channel; and
forming a second gate structure on the semiconductor epitaxial layer.

2. The method for forming the strained semiconductor channel according to claim 1, wherein:
the semiconductor substrate is a Si substrate or a silicon on insulator.

3. The method for forming the strained semiconductor channel according to claim 1, wherein:
the percentage of Ge atom in the relaxed SiGe layer gradually varies from about 20% to 100% away from the semiconductor substrate.

4. The method for forming the strained semiconductor channel according to claim 1, wherein:
the dopants used in the ion implantation are P, As, or the combination of P and As.

5. The method for forming the strained semiconductor channel according to claim 1, wherein:
the dosage of the ion implantation is in a range of about 5×10¹³−4×10¹⁵ cm⁻³, and the implantation energy is about 1 k-3 keV.

6. The method for forming the strained semiconductor channel according to claim 1, wherein:
the depth of the ion implantation region is formed to be about 3 nm-10 nm by the ion implantation.

7. The method for forming the strained semiconductor channel according to claim 1, further comprising:
after performing the ion implantation, performing annealing within a temperature range of about 700-800° C.

8. The method for forming the strained semiconductor channel according to claim 1, wherein:
the etching of the ion implantation region is implemented by dry etching that makes use of NF³ and Cl².

9. The method for forming the strained semiconductor channel according to claim 1, wherein:
the semiconductor epitaxial layer comprises at least one of a Si epitaxial layer, a Ge epitaxial layer, and a SiGe epitaxial layer.

10. The method for forming the strained semiconductor channel according to claim 9, wherein:
the semiconductor epitaxial layer has a thickness of about 5-10 nm.
